(19) United States
(12) Patent Application Publication
(10) Pub. No.: US 2025/0277307 A1
(43) Pub. Date: Sep. 4, 2025

(54) 3D PRINTED INTEGRATED GAS MIXER

(71) Applicant: Applied Materials, Inc., Santa Clara, CA (US)

(72) Inventors: Shashank SHARMA, Raipur (IN); Sandeep KUMPALA, Bangalore (IN); Sandesh HEMADRI, Bangalore (IN); Akshay DHANAKSHIRUR, Hubli (IN)

(21) Appl. No.: 19/063,607

(22) Filed: Feb. 26, 2025

(30) Foreign Application Priority Data
Mar. 1, 2024 (IN) 202441015287

(51) Int. Cl. C23C 16/455

(52) U.S. Cl. CPC C23C 16/45512; C23C 16/45544; C23C 16/45591

(57) ABSTRACT

Embodiments of the present disclosure generally relate to mixing gases for deposition processes. Specifically, the disclosure relates to a 3D printed single piece gas mixer that mixes a plurality of gases prior to the gases entering a processing chamber. In one embodiment a mixer is provided. The mixer includes a body, an inlet, an outlet, and a hollow passage. The hollow passage is disposed through the body and fluidly connects the inlet to the outlet. The hollow passage includes a sidewall. The mixer further includes a plurality of fins formed on the sidewall. The plurality of fins extend into the hollow passage, and the plurality of fins and the sidewall form a monolithic structure.

### CROSS-REFERENCE TO RELATED APPLICATION

This application claims priority to Indian Provisional Application No. 202441015287, filed Mar. 1, 2024, which is incorporated by reference herein in its entirety.

### BACKGROUND

### Field

Embodiments of the present disclosure generally relate to mixing gases for deposition processes. Specifically, the disclosure relates to a 3D printed single piece gas mixer that mixes a plurality of gases prior to the gases entering a processing chamber.

### Description of the Related Art

Atomic layer deposition (ALD) is a process performed in semiconductor manufacturing. ALD implements multiple deposition steps using different gases to deposit material on a substrate. After ALD processes, cleaning processes that use different gases are performed. Each step of the process requires multiple gases and these gases are mixed prior to entering a processing volume. Mixing the gases is critical to proper deposition of material on the substrate.

Longer mixing lengths provide better mixing of gases. However, due to design constraints on length in processing chambers, gas mixers are used to mix the gases. Therefore, what is needed in the art is new gas mixers for mixing gases.

### SUMMARY

In one embodiment a mixer is provided. The mixer includes a body, an inlet, an outlet, and a hollow passage. The hollow passage is disposed through the body and fluidly connects the inlet to the outlet. The hollow passage includes a sidewall. The mixer further includes a plurality of fins formed on the sidewall. The plurality of fins extend into the hollow passage, and the plurality of fins and the sidewall form a monolithic structure.

In another embodiment, a processing chamber is provided. The processing chamber includes a chamber body defining a processing volume. The chamber body includes a gas box having a port, and a bottom. The processing chamber further includes a mixer disposed on the lid and fluidly connected to the port. The mixer includes a body, an inlet, an outlet fluidly connected to the processing volume of the chamber body, and a hollow passage. The hollow passage is disposed through the body, and fluidly connects the inlet to the outlet. The hollow passage includes a sidewall. The mixer further includes a plurality of fins formed on the sidewall. The plurality of fins extend into the hollow passage, and the plurality of fins and the sidewall form a monolithic structure. The processing chamber further includes a plurality of gas lines fluidly connected to the inlet of the mixer.

In another embodiment, a method of mixing gases is provided. The method includes fluidly connecting an inlet of a mixer to a plurality of gas lines, and fluidly connecting an outlet of the mixer to a port of a processing chamber. The mixer includes a body, the inlet, the outlet, and a hollow passage. The hollow passage is disposed through the body and fluidly connects the inlet to the outlet. The hollow passage includes a sidewall. The mixer further includes a plurality of fins formed on the sidewall. The plurality of fins extend into the hollow passage, and the plurality of fins and the sidewall form a monolithic structure. The method further includes flowing a first gas and a second gas through the gas lines and into the mixer to produce a mixed gas, and flowing the mixed gas through the outlet of the mixer and into a processing volume of the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic, side view of a processing chamber with a substrate support, according to embodiments.

FIG. 2A is a schematic, cross sectional view of a gas mixer, according to embodiments.

FIG. 2B is a schematic, isometric view of a gas mixer, according to embodiments.

FIG. 3 is a flow diagram of a method for mixing gases, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to mixing gases for atomic layer deposition processes. Specifically, the disclosure relates to a 3D printed single piece gas mixer that mixes a plurality of gases prior to the gases entering processing chambers.

Current mixer designs have two parts, a mixer part and a spacer part, for the mixer to operate. The mixer part mixes the gases between the spacer part. However, two-part mixers have several drawbacks. For example, in two-part mixers, the mixer part moves relative to the spacer part. The movement of the mixer part can lead to particle generation. Another issue with the two-part mixer is the mixer part can also tilt in the spacer part, affecting deposition on a substrate during processing. The two-part mixer can also be damaged when installed in a processing chamber. Additionally, the two-part mixer has a high cost and lead time due to the precise machining needed to form the mixing part of the two-part mixer.

In various embodiments, the single piece mixer address these and other design issues of two-part mixers. For example, in various embodiments, the mixer is an integrated mixer and spacer formed by additive manufacturing. In some embodiments, the mixer has a plurality of fins that change the direction of gas flowing through the mixer. Changing the direction of the gas mixes the gas. Further, the mixer does not have a risk of particle generation or mixer tilting due to the mixer being formed as a single part. The single part design of the mixer also reduces the risk of damage during installation in process chambers. In addition, the mixer can be formed via additive manufacturing, reducing cost and lead time.

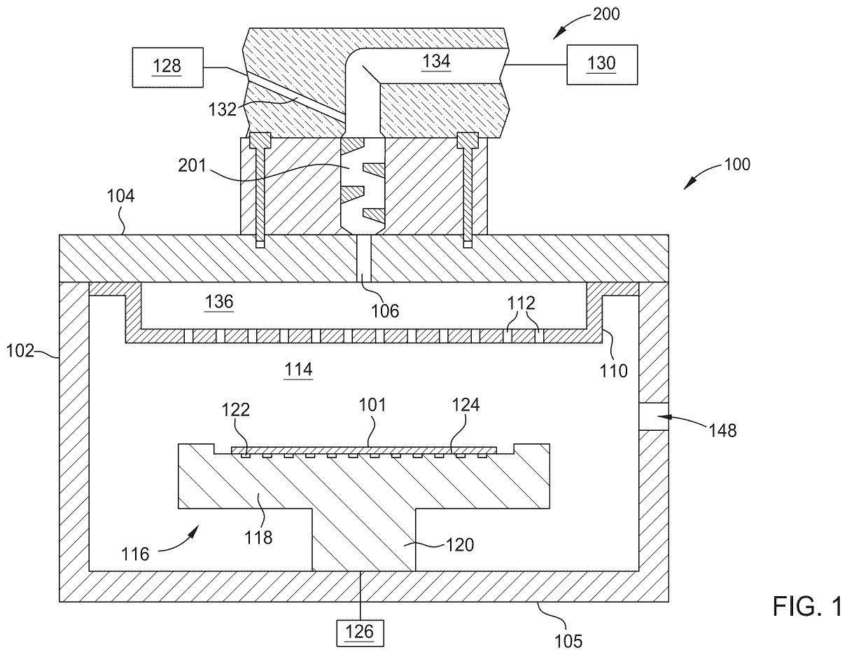

FIG. 1 is a schematic, side view of a processing chamber 100 with a substrate support 116. The process chamber 100 includes a chamber body 102 and a gas box 104 defining a process volume 114 therein. A bottom 105 of the chamber body 102 is opposite the gas box 104. A port 106 is formed through the gas box 104. A gas mixer 200 is in fluid communication with the port 106. A showerhead 110 is coupled to the gas box 104. A plurality of openings 112 are formed through the showerhead 110. The gas mixer 200 is in fluid communication with the process volume 114 via the port 106 and the openings 112.

A substrate support 116 is moveably disposed in the process volume 114 opposite the gas box 104. The substrate support 116 includes a support body 118 disposed on a stem 120. The support body 118 includes a support surface 122 disposed opposite the stem 120 and facing the showerhead 110. The support surface 122 includes a plurality of mesas 124. An opening 148 is formed through the chamber body 102 between the gas box 104 and the bottom 105. During operation, a substrate 101 is loaded onto the support surface 122 through the opening 148. An actuator 126 is coupled to the substrate support 116 to move the substrate support 116 toward and away from the showerhead 110 for loading and processing the substrate 101 thereon. Although the processing chamber 100 described herein is provided as an example of a chamber with which the single piece mixer can be implemented, in various embodiments, the single piece mixer can be implemented with other types of processing chambers.

The gas mixer 200 is fluidly connected to a first gas source 128 and a second gas source 130. In some embodiments, the gas mixer 200 is fluidly connected to other gas sources. The first gas source 128 is fluidly connected to the gas mixer 200 with a first gas line 132. The second gas source 130 is fluidly connected to the gas mixer 200 with a second gas line 134. Gas enters the gas mixer 200 and mixes in a hollow passage 201. The hollow passage 201 extends through the gas mixer 200 fluidly connecting the gas sources 128, 130 to the port 106. The gas exits the port into a showerhead volume 136 defined by the gas box 104 and the showerhead 110. The gas box 104 is an RF hot point on the process chamber 100. The gas box 104 contains one of a plurality of electrodes (not shown) for plasma generation.

The process chamber 100 is used for atomic layer deposition (ALD) processes. ALD processes include at least two deposition steps and at least two purging steps. A deposition step will be followed by a purging step to remove unused deposition gases in the process chamber 100. During a first deposition step, the first gas may be a precursor gas. Different precursor gases may be used for different deposition steps. During the first deposition step, the second gas may be a purge gas. The purge gas is a RPS purge gas. The purge gas includes at least one of argon gas, or a similar gas. Mixing the precursor gas and the purge gas is critical to the thickness uniformity on the substrate 101 during processing. During a first purge step, the purge gas is flowed through the first gas line 132 to remove unused precursor gases. The purge gas may be oxygen gas (O₂) or a gas suitable to rid the gas line 132 of the unused precursor gas from the first deposition step. During the first purge step, the purge gas from the first deposition step is flowed through the second gas line 134. A second deposition step is performed after the first purge step. The second deposition step can include a different precursor gas. After the second deposition step, a second purge step is performed. In some embodiments, additional deposition steps and purge steps may be performed. In some embodiments, for example, the first deposition step includes a precursor gas that contains silicon and the second deposition gas includes a precursor gas of oxygen (O₂). That deposition would form silicon dioxide (SiO₂) on the substrate 101. During ALD processes, the second gas line 134 is flowing the second gas at all steps.

After the ALD process is complete, a cleaning process is performed. The cleaning process removes unwanted material deposited on the process chamber 100. During the cleaning process, the first gas is a purge gas. The purge gas may include the purge gases described above. During the cleaning process, the second gas is a clean gas. The clean gas includes at least one of nitrogen trifluoride (NF₃), fluorine radicals, oxygen (O₂), or different gases compatible with cleaning the selected precursor gas. Mixing the cleaning gas and the purge gas is critical to the cleaning process and the gases mixed in the gas mixer 200.

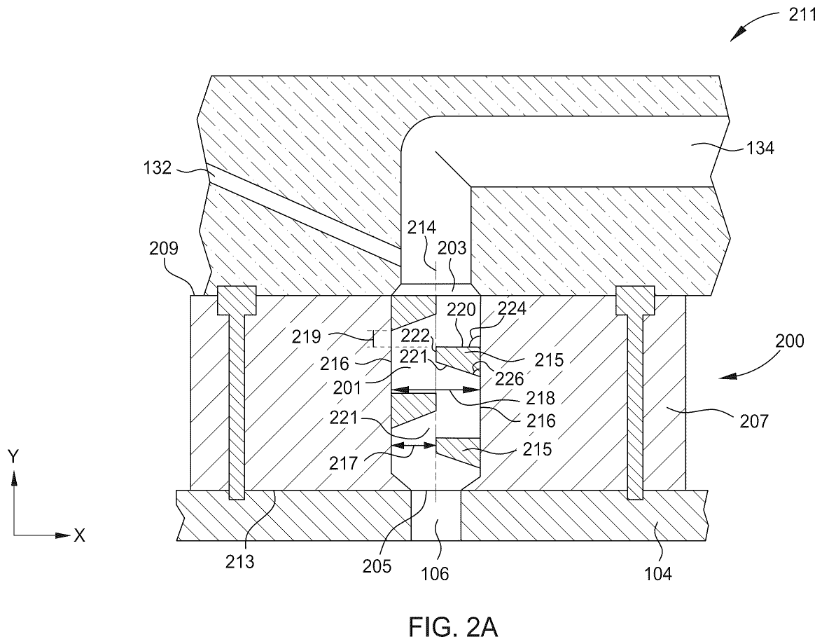

FIG. 2A is a schematic, cross sectional view of a gas mixer 200. The gas mixer 200 includes an inlet 203, an outlet 205, and an interior section 207. The inlet 203 is positioned on a first surface 209 of the gas mixer 200. The inlet 203 is fluidly connected to the first gas line 132 and the second gas line 134. The inlet 203 is also fluidly connected to the interior section 207. The first gas line 132 enters the inlet 203 at an angle. The second gas line 134 enters the inlet 203 vertically. The inlet 203 may be shaped as a semicircular flange. In some embodiments, a gas assembly 211 is positioned on the first surface 209 of the gas mixer 200. The gas assembly 211 includes the first gas line 132 and the second gas line 134. The gas assembly 211 is a RF ground point. The gas assembly 211 is at a low voltage compared to the gas box 104. The outlet 205 is positioned on a second surface 213 of the gas mixer 200. The outlet 205 is fluidly connected to the port 106. The outlet 205 is also fluidly connected to the interior section 207. The second surface 213 is disposed on the gas box 104 of the processing chamber 100. A body of the gas mixer is defined by the interior section 207, the first surface 209, and the second surface 213.

The hollow passage 201 extends through the interior section 207 from the inlet 203 to the outlet 205. In one or more embodiments, the hollow passage 201 includes a sidewall 216. A plurality of fins 215 are formed on the sidewall 216. Further, the sidewall 216 extends around the hollow passage 201. The plurality of fins 215 and the sidewall 216 form a monolithic structure in the gas mixer 200 (e.g., the sidewall 216 and the plurality of fins 215 include the same material and the sidewall 216 and the plurality of fins 215 are inseparable). In one or more embodiments, the plurality of fins 215 are formed on the interior section 207 to form the monolithic structure in the gas mixer 200 (e.g., the interior section 207 and the plurality of fins 215 include the same material and the interior section 207 and the plurality of fins 215 are inseparable). In one or more embodiments, the hollow passage 201 includes a sleeve (not pictured). The sleeve includes an interior wall and an exterior wall where the exterior wall contacts the interior section 207 and interior wall contacts the hollow passage 201. The plurality of fins 215 are formed on the interior wall of the sleeve such that the plurality of fins 215 and the sleeve form a monolithic structure in the gas mixer 200 (e.g., the sleeve and the plurality of fins 215 include the same material and the sleeve and the plurality of fins 215 are inseparable).

The fins 215 have a first surface 220, a second surface 221 and an edge surface 222. The first surface 220 extends from the sidewall 216 at a first angle 224. The first angle 224 may be about 70 degrees to about 110 degrees, such as about 80 degrees to about 100 degrees, such as about 85 degrees to about 95 degrees, such as about 90 degrees. The second surface 221 extends from the sidewall 216 at a second angle 226. The second angle 226 may be about 20 degrees to about 80 degrees, such as about 30 degrees to about 70 degrees, such as about 40 degrees to about 65 degrees, such as about 45 degrees to about 60 degrees. The second angle 226 is calculated from the sidewall 216 counter-clockwise to the second surface 221 as shown in FIG. 2A. The second angle 226 is selected to give the fin 215 structural strength in the hollow passage 201. The first surface 220 is opposite the second surface 221. The edge surface 222 connects the first surface 220 to the second surface 221. Further, the edge surface is opposite the sidewall 216. The edge surface 222 is an extended surface of each fin 215 positioned within the hollow passage 201. Additionally, one fin 215 is not connected to another fin 215, the fins 215 are connected only to the sidewall 216. The fins 215 disrupt the linear path of the hollow passage 201 from the inlet 203 to the outlet 205. The plurality of fins 215 includes at least three fins 215.

The fins 215 change the direction of gases through the hollow passage 201 and a cross-sectional area through the hollow passage 201. By changing the direction of the gases, the fins 215 cause the gases to enter turbulent flow. The turbulent flow mixes the gases. The plurality of fins 215 cause the gases traveling through the hollow passage 201 to cross a center axis 214 of the hollow passage 201, the center axis 214 extending from the inlet 203 to the outlet 205. The fins 215 narrow the path through the hollow passage 201 from a first cross-sectional area 218 to a second cross-sectional area 217 and a third cross-sectional area 219. Further, the first cross-sectional area 218 is defined as the area between the sidewall 216 without the fins 215 obstructing the path. The first cross-sectional area 218 is about 0.5 in² to about 1.5 in², such as about 0.6 in² to about 1 in², such as about 0.8 in². The diameter creating the first cross-sectional area 218 is about 0.6 in to about 1.4 in, such as about 1 in. The second cross-sectional area is the area in the path in a Y-direction between the sidewall 216 with a fin 215 obstructing part of the path. The second cross-sectional area 217 is about 0.1 in² to about 0.9 in², such as about 0.3 in² to about 0.5 in², such as about 0.4 in². The diameter creating the second cross-sectional area 217 is about 0.3 in to about 1 in, such as about 0.5 in to about 0.8 in. In addition, the third cross-sectional area 219 is defined as the cross-sectional area between fins 215 in an X-direction. The third cross-sectional area 219 is about 0.005 in² to about 0.1 in², such as about 0.01 in² to about 0.02 in². The diameter creating the third cross-sectional area 219 is about 0.05 in to about 0.4 in, such as about 0.1 in to about 0.2 in. In various embodiments, the third cross-sectional area 219 is less than the second cross-sectional area 217. The second cross-sectional area 217 is less than the first cross-sectional area 218. For example, in some embodiments, the second cross-sectional area 217 is constant throughout the hollow passage 201 due to the fins being the same length. In other embodiments, the second cross-sectional area 217 varies throughout the hollow passage 201 due to the fins 215 having different lengths. In various embodiments, the third cross-sectional area 219 is constant throughout the hollow passage 201 due to the fins 215 being spaced equidistant. In other embodiments, the third cross-sectional area 219 varies throughout the hollow passage 201 due to the varied spacing of the fins 215. The fins 215 alternate the cross-sectional area of the hollow passage 201 between the second cross-sectional area 217 and the third cross-sectional area 219. Varying the cross-sectional area of the hollow passage 201 assists in mixing the gases. By attaching the fins 215 to the sidewall 216, the gas mixer 200 does not have any extra volume added to the hollow passage 201. For ALD processes, reduction of volume in the gas mixer 200 is beneficial as reduction of the volume leads to a quicker evacuation of gases from the gas mixer 200, decreasing the cycle time of the ALD process. Timing of the flowing of the gases is critical in the ALD process. By having the fins 215 integrated into the gas mixer 200, the volume of components that would mount the fins 215 in the gas mixer 200 is eliminated, reducing the volume of the gas mixer 200. Therefore, the gas mixer 200 has the benefit of not slowing down the process by exposing the gases to extra volume compared to two-part mixers.

The fins 215 change the direction of a path that the gas flows through the hollow passage 201, for example, by creating turbulent flow. The path starts in the inlet 203 in a Y-direction. The path changes direction at a fin 215 causing the path to move in a first X-direction. The path continues in the first X-direction until the path contacts the sidewall 216 causing the path to move in the Y-direction. The path contacts another fin 215 causing the path to move in a second X-direction. The path continues to change directions as described above until the path contacts the sidewall 216 for the last time. Finally, the path then moves in the Y-direction towards the outlet 205. The amount of fins 215 is optimized to increase the efficiency of the ALD process. Increasing the number of fins 215 increases the mixing of the gases but also increases the amount of time required for the gases to reach the processing volume 114. Decreasing the amount of fins 215 reduces the time required for the gases to reach the processing volume 114, but too few fins 215 cannot ensure proper mixing. The type of gases used in the ALD process can affect the optimal amount of fins 215. The hollow passage 201 may include three fins 215 to four fins 215, such as four fins 215. The changing of direction of the path causes the gases to be mixed when flowing through the path of the hollow passage 201. This mixing reduces the length required for the gas mixer 200.

FIG. 2B is a schematic, isometric view of a gas mixer 200. FIG. 2B illustrates the inlet 203 and a plurality of fastener ports 223 extend from the first surface 209 of the gas mixer 200 to the second surface 213. The fastener ports 223 are configured to attach the first surface 209 to the gas lines and/or the gas assembly 211. The fastener ports 223 are also configured to attach the second surface 213 to the gas box 104 of the processing chamber 100. The interior section 207 is between the first surface 209 and second surface 213. The hollow passage 201 is disposed through the interior section 207. FIG. 2B illustrates the gas mixer 200 having a body with a cylindrical shape. The cylindrical shape has a diameter 225 that is determined based on design constrains and space availability above the process chamber 100. The cylindrical shape has a mixer thickness 227 that is determined based on design constrains and space availability above the process chamber 100. In some embodiments, the gas mixer 200 has a different shape (e.g., rectangular, oval, polygonal, etc.).

The gas mixer 200 is formed from a ceramic material. In various embodiments, the ceramic material includes at least one of aluminum oxide (Al₂O₃), aluminum nitride (AlN), or a similar material. The ceramic material allows the gas mixer 200 to act as a barrier between the RF hot gas box 104 of the processing chamber 100 and the RF ground gas assembly 211. The ceramic material allows a voltage difference to exist between the gas box 104 (e.g., held at a higher voltage) and the gas assembly 211 (e.g., held at a lower voltage). When performing the cleaning process with fluorine radicals, surface recombination is an issue. Surface recombination causes two fluorine radicals to combine into fluorine gas when coming into contact with a surface. Fluorine gas does not react with the unwanted deposited material removed during the cleaning process. Therefore, fluorine gas reduces the cleaning efficiency of the cleaning process. The ceramic material reduces the surface recombination increasing the cleaning efficiency. Ceramic materials cause surface recombination at a rate that is significantly slower than aluminum materials (e.g., less than 10% the rate of surface recombination in aluminum materials). In some embodiments, the gas mixer 200 is formed from an aluminum alloy.

The gas mixer 200 is formed in an additive manufacturing process (e.g., 3D printing). The additive manufacturing process allows for internal features (e.g., the fins 215) to be formed in the gas mixer 200. Conventional manufacturing cannot form such internal features in the gas mixer 200. Accordingly, processes such as 3D printing reduce the cost and lead time of manufacturing the gas mixer 200. The 3D printing process may form a gas mixer 200 that has a purity of material greater than or equal to 99.5%, such as 99.8%. Such a high purity allows for lower defects on the substrate 101, better material properties, and reduction of a risk of outgassing.

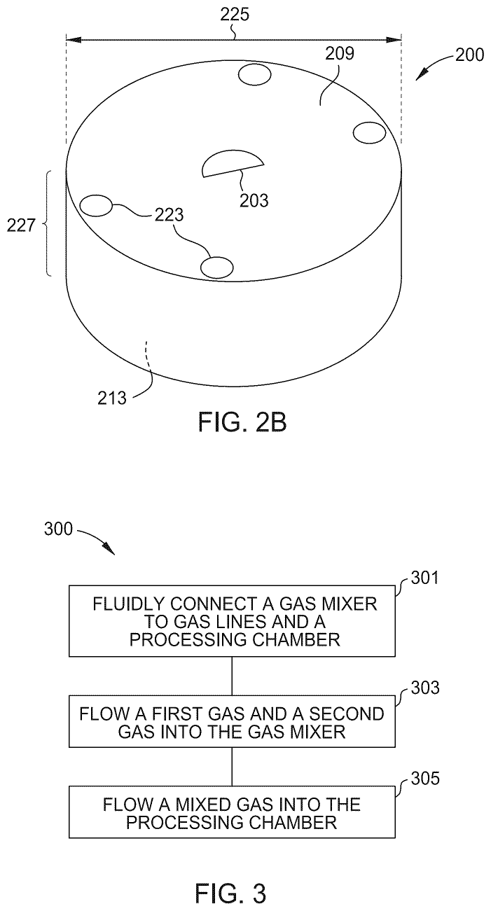

FIG. 3 is a flow diagram of a method 300 for mixing gases. At operation 301, the inlet 203 of the gas mixer 200 is fluidly connected to the plurality of gas lines and the outlet 205 of the gas mixer 200 is fluidly connected to the port 106 of the processing chamber 100. The gas mixer 200 is described in FIGS. 2A and 2B.

At operation 303, the first gas and the second gas are flowed into the gas mixer 200. The first gas and the second gas flow to the inlet 203 of the gas mixer 200. During the deposition process, the first gas is the precursor gas, and the second gas is the purge gas. During the cleaning process, the first gas is the purge gas, and the second gas is the cleaning gas. The first gas flows from the first gas source 128 to the inlet 203 via the first gas line 132. The second gas flows from the second gas source 130 to the inlet 203 via the second gas line 134. The path that the gases enter the inlet 203 is in the Y-direction. The first gas and the second gas are mixed in the gas mixer 200. The gases are mixed by flowing through the path of the hollow passage 201. The gases are mixed while changing directions in the hollow passage 201. The plurality of fins 215 change the direction of the hollow passage 201. The path of the gases through the hollow passage 201 is described in FIG. 2A. The gases undergo turbulent flow. The gas mixer 200 produces a mixed gas. The mixed gas then moves in the Y-direction towards the outlet 205.

At operation 305, the mixed gas flows out the gas mixer 200 into the processing volume 114. After moving towards the outlet 205, the mixed gas exits the gas mixer 200 through the outlet 205. Further, the mixed gas passes through the outlet 205 into the port 106. After passing through the port 106, the mixed gas enters the showerhead volume 136. The mixed gas travels through the showerhead volume 136 to the showerhead 110. At the showerhead 110, the mixed gas travels through the openings 112 into the processing volume 114. During the depositing process, the mixed gas then is used in processing to deposit material on the substrate 101. During the cleaning process, the mixed gas cleans the surfaces the mixed gas contacts.

In summation, embodiments of the present disclosure generally relate to mixing gases for deposition processes, such as atomic layer deposition. Specifically, the disclosure relates to a single piece gas mixer that mixes a plurality of gases prior to the gases entering the processing chamber. The gas mixer integrates the mixer and spacer by using fins in a hollow passage. The gas mixer is formed in an additive manufacturing process. Benefits of the gas mixer include reducing the risk of particle generation and reducing the risk of damage. The gas mixer has increased repairability and cannot become tilted due to the gas mixer being one continuous part. The additive manufacturing process used to form the gas mixer reduces the cost and lead time of forming the gas mixers.

While the foregoing is directed to embodiments of the present disclosure, other and further embodiments of the disclosure may be devised without departing from the basic scope thereof, and the scope thereof is determined by the claims that follow.

What is claimed is:

1. A mixer, comprising:
a body;
an inlet;
an outlet;
a hollow passage disposed through the body and fluidly connecting the inlet to the outlet, the hollow passage comprising a sidewall; and
a plurality of fins formed on the sidewall and extending into the hollow passage, wherein the plurality of fins and the sidewall form a monolithic structure.

2. The mixer of claim 1, wherein the plurality of fins cause a gas traveling through the hollow passage to cross a center axis of the hollow passage, the center axis extending from the inlet to the outlet.

3. The mixer of claim 1, wherein each fin in the plurality of fins comprises:
a first surface extending from the sidewall at a first angle;
a second surface extending from the sidewall at a second angle, the second surface opposite the first surface; and
an edge surface connecting the first surface to the second surface, the edge surface opposite the sidewall and positioned within the hollow passage.

4. The mixer of claim 3, wherein:
the first angle is between 80 degrees and 100 degrees; and
the second angle is between 30 degrees and 70 degrees.

5. The mixer of claim 3, wherein:
the first angle is between 85 degrees and 95 degrees; and
the second angle is between 40 degrees and 65 degrees.

6. The mixer of claim 1, wherein the plurality of fins includes at least three fins.

7. The mixer of claim 1, wherein the body comprises a ceramic material, the ceramic material reducing surface recombination of radicals in a gas configured to pass through the hollow passage.

8. The mixer of claim 1, wherein the monolithic structure is formed using an additive manufacturing process.

9. A processing chamber, comprising:
a chamber body defining a processing volume, the chamber body comprising:
a gas box having a port; and
a bottom;
a mixer disposed on the gas box and fluidly connected to the port, the mixer comprising:
a body;
an inlet;
an outlet fluidly connected to the processing volume of the chamber body;
a hollow passage disposed through the body and fluidly connecting the inlet to the outlet, the hollow passage comprising a sidewall; and
a plurality of fins formed on the sidewall and extending into the hollow passage, wherein the plurality of fins and the sidewall form a monolithic structure; and
a plurality of gas lines fluidly connected to the inlet of the mixer.

10. The processing chamber of claim 9, wherein the plurality of fins cause a gas traveling through the hollow passage to cross a center axis of the hollow passage, the center axis extending from the inlet to the outlet.

11. The processing chamber of claim 9, wherein each fin in the plurality of fins comprises:
a first surface extending from the sidewall at a first angle;
a second surface extending from the sidewall at a second angle, the second surface opposite the first surface; and
an edge surface connecting the first surface to the second surface, the edge surface opposite the sidewall and positioned within the hollow passage.

12. The processing chamber of claim 11, wherein:
the first angle is between 80 degrees and 100 degrees; and
the second angle is between 110 degrees and 150 degrees.

13. The processing chamber of claim 9, wherein the plurality of gas lines are disposed in a gas assembly, the plurality of gas lines configured to flow a plurality of gases towards the inlet of the mixer.

14. The processing chamber of claim 13, wherein the plurality of gases includes a precursor gas and a purge gas.

15. The processing chamber of claim 14, wherein a gas line for the precursor gas enters the inlet at an angle relative to a first direction, and a gas line for the purge gas enters the inlet in the first direction.

16. The processing chamber of claim 9, wherein the mixer comprises a ceramic material.

17. A method of mixing gases, comprising:
fluidly connecting an inlet of a mixer to a plurality of gas lines;
fluidly connecting an outlet of the mixer to a port of a processing chamber, the mixer comprising:
a body;
the inlet;
the outlet;
a hollow passage disposed through the body and fluidly connecting the inlet to the outlet, the hollow passage comprising a sidewall; and
a plurality of fins formed on the sidewall and extending into the hollow passage, wherein the plurality of fins and the sidewall form a monolithic structure;
flowing a first gas and a second gas through the gas lines and into the mixer to produce a mixed gas; and
flowing the mixed gas through the outlet of the mixer and into a processing volume of the processing chamber.

18. The method of claim 17, further comprising performing at least one deposition process with the mixed gas, the first gas comprising a precursor gas, and the second gas comprising a purge gas.

19. The method of claim 17, further comprising performing at least one cleaning process with the mixed gas, the first gas comprising a purge gas, and the second gas comprising a cleaning gas.

20. The method of claim 17, further comprising, prior to flowing the mixed gas through into the processing volume, passing the mixed gas through the outlet to the port of the processing chamber and through a showerhead disposed in the processing chamber.
